(19) United States
(12) Patent Application Publication
(10) Pub. No.: US 2026/0191057 A1
(43) Pub. Date: Jul. 2, 2026

(54) ELECTRONIC DEVICE INCLUDING COMMON PLATFORM STRUCTURE AND MANUFACTURING METHOD THEREOF

(71) Applicant: 3DMMIC LLC., Taoyuan City (TW)

(72) Inventors: Chin-Chi Chang, Taoyuan City (TW); Shih-Hsun Hsu, Taoyuan City (TW); Min-Jui Chen, Taoyuan City (TW); Shih-Chun Lee, Taoyuan City (TW)

(73) Assignee: 3DMMIC LLC., Taoyuan City (TW)

(21) Appl. No.: 19/425,972

(22) Filed: Dec. 18, 2025

Related U.S. Application Data
(60) Provisional application No. 63/739,099, filed on Dec. 26, 2024.

(51) Int. Cl. H10W 70/652; H10D 80/20; H10W 70/05; H10W 70/09

(52) U.S. Cl. CPC H10W 70/652; H10D 80/20; H10W 70/09; H10W 70/095

(57) ABSTRACT

An electronic device and a manufacturing method thereof are provided. The electronic device includes a substrate, an active device disposed over the substrate, an interconnect structure disposed over and electrically coupled to the active device, a passive device disposed over the active device and embedded in the interconnect structure, a common platform structure comprising a first portion and a second portion connected to the first portion. The passive device is electrically coupled to the active device through the interconnect structure. The first portion is vertically between the active device and the passive device, and a portion of the active device is electrically and thermally coupled to the first portion, and the passive device is laterally encircled by the second portion.

### CROSS-REFERENCE TO RELATED APPLICATION

This application claims the priority benefit of U.S. provisional application serial no. 63/739,099, filed on December 26^{th}, 2024. The entirety of the above-mentioned patent application is hereby incorporated by reference herein and made a part of this specification.

### BACKGROUND

### Technical Field

The present disclosure relates to an electronic device and a manufacturing method thereof and more specifically relates to an integrated microelectronic device including a common platform structure and a manufacturing method thereof.

### Description of Related Art

As wireless communication technologies continue to advance, the demand for wireless devices with integrated and multifunctional capabilities has surged. To meet these needs, the dimensions of individual circuit components within wireless devices have been significantly reduced, while the overall cost of components has continued to decline. A prominent solution garnering attention in recent years is three-dimensional integrated circuit (3DIC) technology. Unlike conventional ICs, which rely on lateral arrangement of devices, 3DIC technology leverages vertical stacking of devices, drastically reducing the footprint of the IC. However, as the size of ICs continues to shrink, effective thermal management within these densely packed layers becomes increasingly challenging. Ensuring efficient heat dissipation in 3DICs has therefore emerged as a critical design issue, necessitating innovative approaches to prevent overheating and to maintain reliable device performance.

### SUMMARY

The disclosure provides an electronic device includes a substrate, an active device disposed over the substrate, an interconnect structure disposed over and electrically coupled to the active device, a passive device disposed over the active device and embedded in the interconnect structure, a common platform structure comprising a first portion and a second portion connected to the first portion. The passive device is electrically coupled to the active device through the interconnect structure. The first portion is vertically between the active device and the passive device, and a portion of the active device is electrically and thermally coupled to the first portion, and the passive device being laterally encircled by the second portion.

The disclosure also provides a manufacturing method of an electronic device. The manufacturing method includes: forming an active device over a substrate; forming a first portion of a common platform structure over the active device, wherein a portion of the active device is connected to the first portion of the common platform structure; forming an interconnect structure over the first portion of the common platform structure; forming a passive device over the first portion of the common platform structure and in the interconnect structure, wherein the active device is electrically coupled to the passive device through the interconnect structure; and forming a second portion of the common platform structure on the first portion and in the interconnect structure, wherein the passive device is laterally encircled by the second portion.

Based on the above, the electronic device of the present disclosure provides a substantial portion of the passive devices stacked over the active devices. The passive devices are fabricated by building up dielectric layers and metallization layers, where the dielectric layers and metallization layers form the interconnect structure. With the stack-up arrangement of passive devices, the footprint of the electronic device may be significantly shrunk. In addition, the electronic device includes the common platform structure having the first portion and the second portion. The second portion (e.g. metal connection paths) extends from the first portion to the top of the electronic device. The common emitter terminals of the active devices are electrically and thermally coupled to the first portion of the common platform structure. Heat generated from the active devices is dispersed more uniformly across the first portion of the common platform structure. The dispersed heat is subsequently transferred to the top of the electronic device and then to the exterior of the electronic device through the second portion of the common platform structure. Heat dissipation of the electronic device may be greatly improved. While the metal connection paths of the common platform structure inherently exhibit inductive characteristics, increasing the number of these paths and minimizing the length of the paths may effectively reduce the undesired grounding inductance at the common emitter terminals.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIGS. 1-3A and 4A are schematic cross-sectional views illustrating a manufacturing method of an electronic device including a common platform structure, in accordance with some embodiments.

FIG. 3B is a schematic plane view showing a relative position of boundaries of a substrate, a common platform structure, and an active region, in accordance with some embodiments.

FIG. 3C is a schematic view illustrating an exemplary layout of various structures at different levels of the structure in FIG. 3A, in accordance with some embodiments.

FIG. 4B is a schematic plane view showing a relative position of boundaries of a substrate, a common platform structure, and distribution areas of active and passive devices, in accordance with some embodiments.

FIG. 4C is a schematic view illustrating an exemplary layout of various structures at different levels of the structure in FIG. 4A, in accordance with some embodiments.

FIGS. 5-6 are schematic cross-sectional views of an electronic device including a common platform structure, in accordance with various embodiments.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

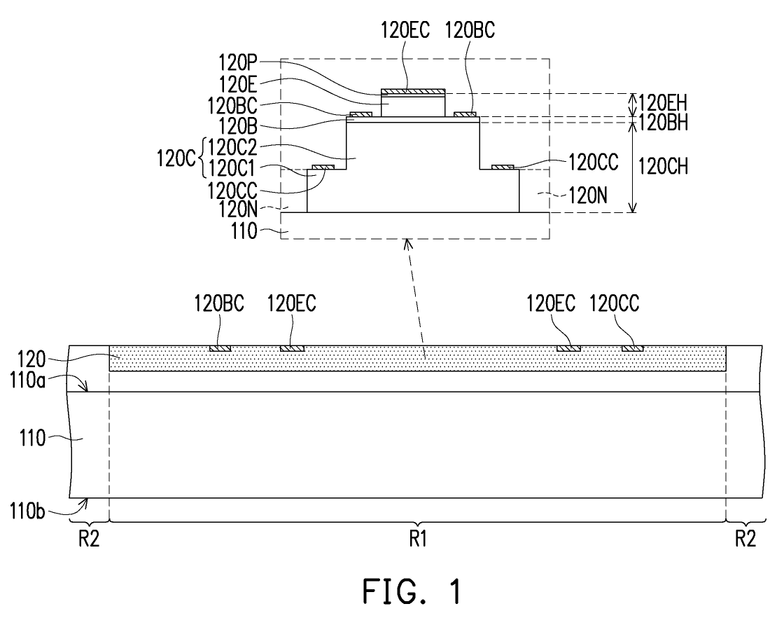

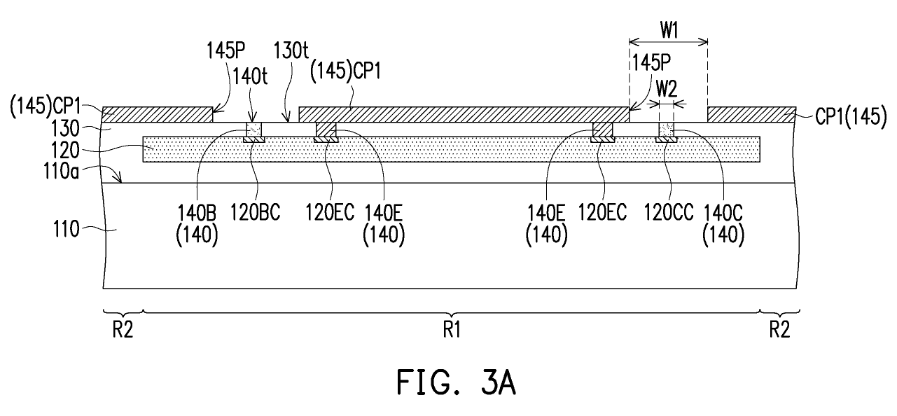

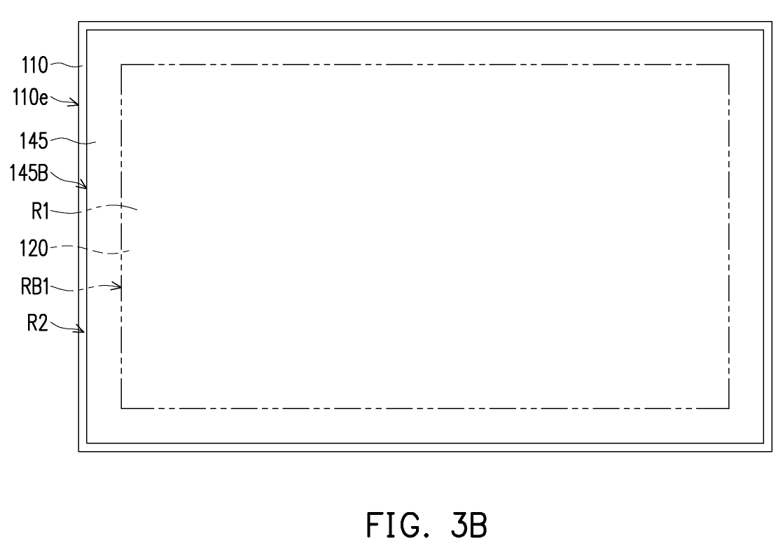

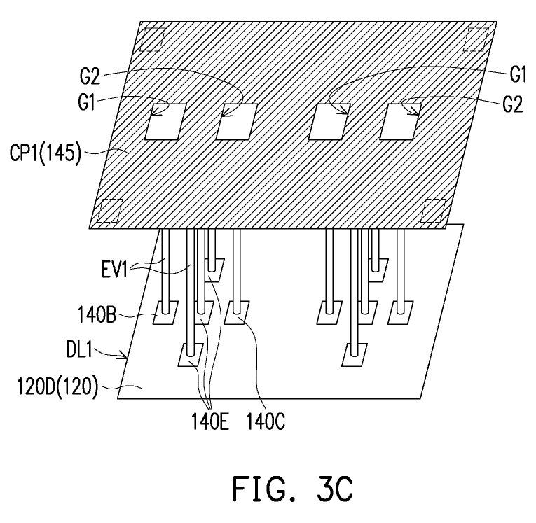

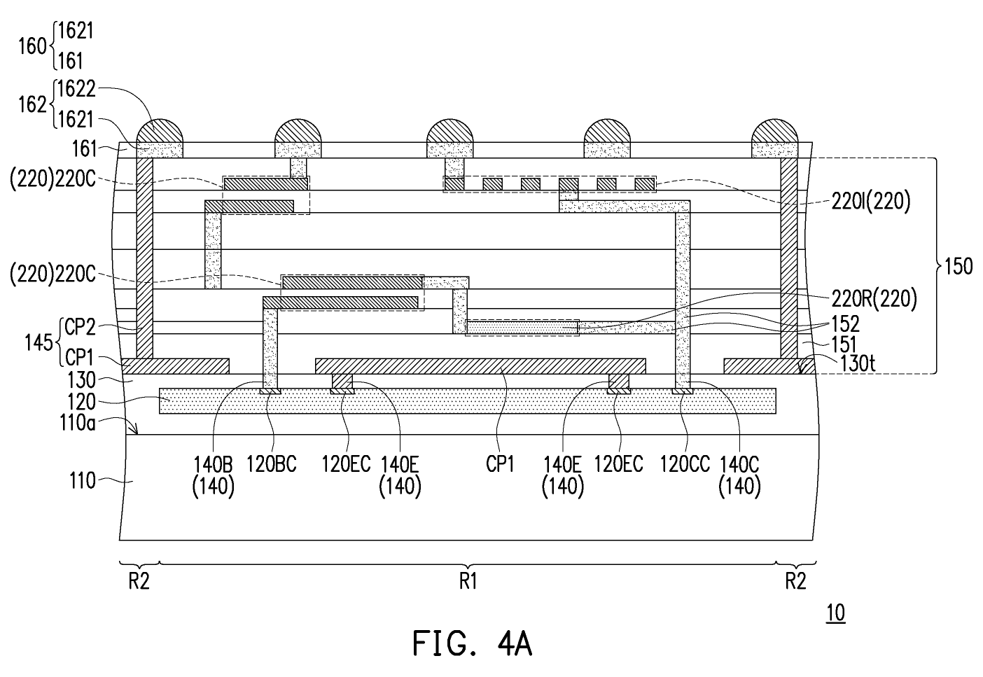

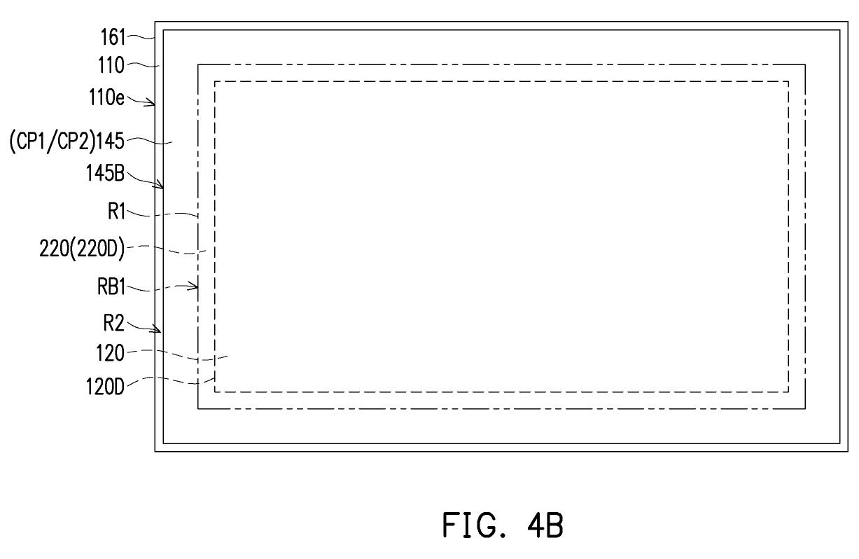

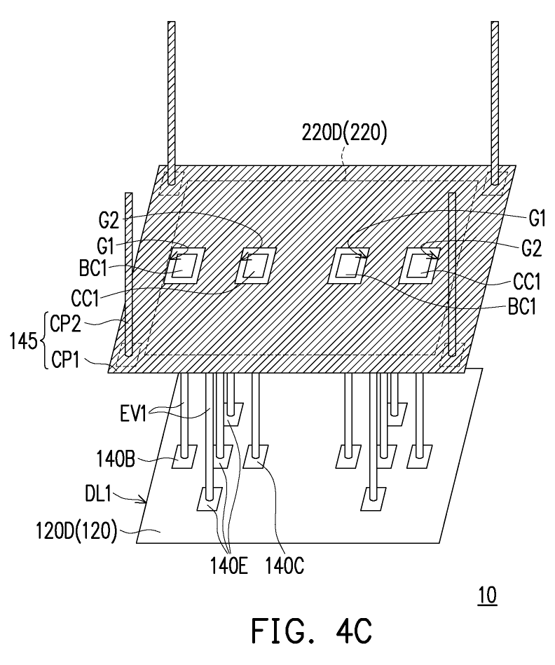

FIGS. 1-3A and 4A are schematic cross-sectional views illustrating a manufacturing method of an electronic device including a common platform structure, FIG. 3B is a schematic plane view showing a relative position of boundaries of a substrate, a common platform structure, and an active region, FIG. 3C is a schematic view illustrating an exemplary layout of various structures at different levels of the structure in FIG. 3A, FIG. 4B is a schematic plane view showing a relative position of boundaries of a substrate, a common platform structure, and distribution areas of active and passive devices, and FIG. 4C is a schematic view illustrating an exemplary layout of various structures at different levels of the structure in FIG. 4A, in accordance with some embodiments.

Referring to FIG. 1, one or more active device(s) 120 is formed over a substrate 110. The substrate 110 includes a first side (or an active side) 110a and a second side (or a backside) 110b opposite to the first side 110a, and the active devices 120 are formed over the first side 110a. In some embodiments, the substrate 110 includes the active region R1 and a peripheral region R2 encircling the active region R1 and the active devices 120 are formed within the active region R1. The substrate 110 includes one or more semiconductor material(s) such as a compound semiconductor including gallium arsenic (GaAs), gallium nitride (GaN), silicon carbide (SiC), indium phosphide (InP), other suitable compound semiconductor, elemental semiconductor (e.g., silicon (Si), germanium (Ge), etc.), the like, a combination thereof (e.g., GaN-on-SiC, SiGe, or the like), etc.

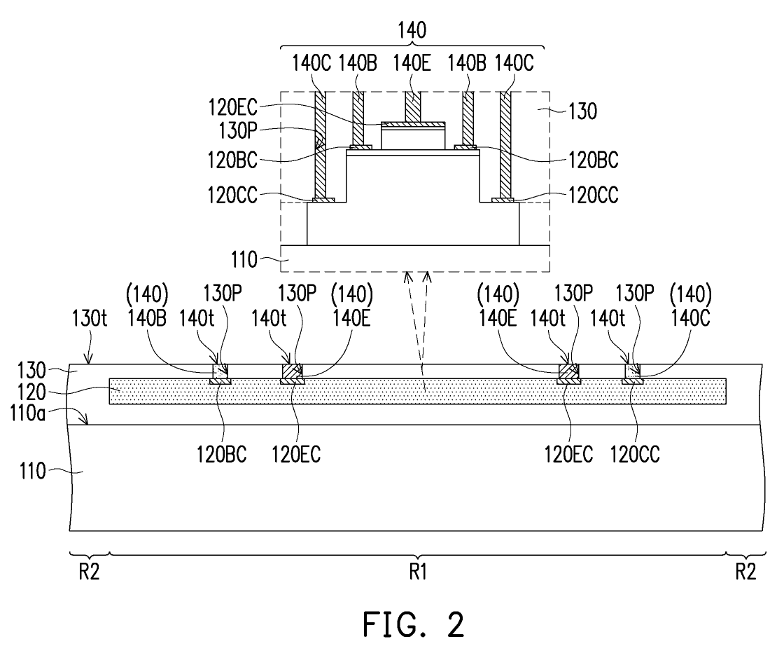

The active devices 120 may be or include transistors such as bipolar transistors (e.g., heterojunction bipolar transistors (HBTs), bipolar junction transistors (BJTs), etc.), field effect transistors (FETs) (e.g., high electron mobility transistors (HEMTs)), diodes, the like, a combination thereof, etc. It should be noted that the lower part of FIG. 1 only shows a box to indicate a distribution area of a great amount of active devices 120 for the sake of simplicity. In some embodiments, referring to the exemplary expanded view shown at the upper part of FIG. 1 where HBT as an exemplary active device, the respective active device 120 includes a sub-collector layer 120C1, a collector layer 120C2, a base layer 120B overlying the collector layer 120C2, an emitter layer 120E overlying the base layer 120B, and a cap layer 120P overlying the emitter layer 120E, where the sub-collector layer 120C1, the collector layer 120C2, the base layer 120B, the emitter layer 120E, and the cap layer 120P are operably coupled as an HBT. As shown in the exemplary expanded view of FIG. 1, the active device 120 implemented as the HBT may have a stepped profile. Such stepped profile may cause the top surface of the subsequently-formed dielectric layer (130 in FIG. 2) to be uneven. In some embodiments, a neutralized epitaxial structure 120N laterally surrounds the sub-collector layer 120C1. Alternatively, the neutralized epitaxial structure 120N is etched off. Therefore, the neutralized epitaxial structure 120N is shown in dashed lines to indicate the non-functionality or non-existence.

With continued reference to the exemplary expanded view shown at the upper part of FIG. 1, the base layer 120B is made of p-type doped material, the emitter layer 120E is made of n-type doped material, and the cap layer 120P is made of n-type doped material, in accordance with some embodiments. For example, the thickness 120EH of the combination of the emitter layer 120E and the cap layer 120P is in a range of about 50 nanometers and 300 nanometers, and the thickness 120BH of the base layer 120B is in a range of about 30 nanometers and 100 nanometers. The base layer 120B may be thinner than the thickness 120EH and the collector layer 120C2. For example, the sub-collector layer 120C1 is made of n-type doped material, and the collector layer 120C2 is made of n-type doped material. The collector layer 120C2 may be formed by using gradient doping technology, and the collector layer 120C2 has a doping concentration lower than that of the sub-collector layer 120C1. For example, the total thickness 120CH of the collector layer 120C2 and the sub-collector layer 120C1 is in a range of about 1000 nanometers and 3500 nanometers. It should be noted that the ranges of the thicknesses provided herein are merely exemplary and may vary depending on product and design requirements.

In some embodiments, the contacts (e.g., including 120CC, 120BC, and 120EC) are respectively formed on the sub-collector layer 120C1, the base layer 120B, and the cap layer 120P overlying the emitter layer 120E. For example, the contacts (e.g., including 120EC, 120BC, and 120CC) may be made of one or more conductive material(s). In some embodiments, the emitter contact 120EC is formed on the top surface of the cap layer 120P, the base contacts 120BC is formed on the top surface of the base layer 120B and disposed alongside the emitter layer 120E, and the collector contacts 120CC is formed on the top surface of the sub-collector layer 120C1 and disposed alongside the collector layer 120C2.

The major applications using HBTs as the active devices 120 may include wireless communication, fiber optic communication, satellite communication, auto-motive electronics, etc. For example, the active devices 120 are implemented as HBTs with excellent high-frequency performance and may be used in power amplifiers in wireless communication devices and base stations. In some embodiments, the active devices 120 are implemented as HBTs for fiber optic communication modules due to HBT’s high electron mobility and excellent frequency response. In some embodiments, the active devices 120 are implemented as HBTs for satellite communication equipment and for power amplification and signal processing due to HBT’s high gain and high-frequency performance. In some embodiments, the active devices 120 are implemented as HBTs for auto-motive electronic system due to HBT’s high reliability and high-power performance.

Referring to FIG. 2 and FIG. 1, a dielectric layer 130 with openings 130P is formed over the substrate 110 across the active region R1 and the peripheral region R2. The active devices 120 may be buried in the dielectric layer 130. In some embodiments where the neutralized epitaxial structure 120N is etched off, the dielectric layer 130 fills the area that was covered by the neutralized epitaxial structure 120N. A plurality of contact plugs 140 is formed in the openings 130P of the dielectric layer 130. In some embodiments, a top surface 130t of the dielectric layer 130 and top surfaces 140t of the contact plugs 140 are substantially level. The dielectric layer 130 may include one or more suitable dielectric material(s) such as silicon nitride, silicon oxide, polyimide, benzocyclobutene (BCB), polybenzoxazole (PBO), the like, a combination thereof, etc. The dielectric layer 130 and the contact plugs 140 may be formed by: depositing a dielectric material layer over the first side 110a of the substrate 110 by any suitable deposition process (e.g., spin-coating, chemical vapor deposition (CVD), physical vapor deposition (PVD), etc.); partially removing the dielectric material layer to form the openings 130P by any suitable removing process (e.g., lithography and etching process, etc.); and forming one or more conductive material(s) in the openings 130P to form the contact plugs 140 which are in physical and electrical contact with the portion of the active devices 120 exposed by the openings 130P. In some embodiments, the dielectric layer 130 has a flat top surface by selecting suitable dielectric material(s) and/or adjusting process parameters during the deposition of the dielectric material(s). In some embodiments, the flat top surface of the dielectric layer 130 is formed by performing a smoothing process (e.g., optimizing process parameters for dielectric formation, selecting suitable polymeric material(s), grinding, etching, and/or rough chemical mechanical polishing (CMP), etc.).

In some embodiments, referring to the exemplary expanded view shown at the upper part of FIG. 2 where HBT as the exemplary active device, the openings 130P expose portions of the collector contacts 120CC, the base contacts 120BC, and the emitter contact 120EC. The contact plugs 140 formed in the openings 130P may thus be in physical and electrical contact with the portions of the collector contacts 120CC, the base contacts 120BC, and the emitter contact 120EC to respectively form collector terminals 140C, base terminals 140B, and an emitter terminal 140E.

Referring to FIGS. 3A-3C and FIG. 2, a first portion CP1 of a common platform structure 145 is formed on the dielectric layer 130 and the contact plugs 140. The first portion CP1 of the common platform structure 145 may be formed as a metallic sheet made of any suitable conductive material (e.g., copper, copper alloys, etc.) and formed by suitable deposition and patterning processes. For example, the first portion CP1 of the common platform structure 145 is made of one or more highly thermally conductive material(s) and functions as a heat dissipation sheet or a heat transfer element. In some embodiments, the first portion CP1 is formed as a thermally conductive metallic strip or band extending horizontally on the top surface 130t of the dielectric layer 130. For example, the first portion CP1 of the common platform structure 145 electrically and thermally couples to at least a portion of the heat generating active devices 120. The first portion CP1 of the common platform structure 145 may be electrically and physically coupled to a portion of the contact plugs 140.

In embodiments where some (or all) of the active devices 120 are implemented as HBTs, the first portion CP1 of the common platform structure 145 is electrically coupled or connected with the common emitter terminals 140E of the underlying active devices 120. In such embodiments, the common platform structure 145 is electrically grounded and functions as a ground bar. It is appreciated that the poor thermal conductivity of the substrate (e.g., GaAs substrate), self-heating and thermal coupling among multiple emitter fingers of an HBT can all possibly lead to local hot spots and thermal instability. In embodiments where the common emitter terminals 140E are connected to the common platform structure 145, the first portion CP1 serves as a heat spreader to disperse the heat more uniformly across the first portion CP1. Thermal runaway effects can be alleviated and thermal stability of the HBT can be enhanced. The dispersed heat is subsequently transferred through the metal connection paths (e.g., the second portion CP2 shown in FIG. 4A) of the common platform structure 145 to the exterior of the resulting electronic device. Heat dissipation of the resulting electronic device may be improved over the conventional monolithic microwave integrated circuit (MMIC) die.

In some embodiments, the first portion CP1 of the common platform structure 145 includes openings 145P, and the other portion of the contact plugs 140 not coupled to the first portion CP1 of the common platform structure 145 may be exposed by the openings 145P. In some embodiments where some (or all) of the active devices 120 are implemented as HBTs, the base terminals 140B and the collector terminals 140C are not electrically connected with the common platform structure 145. The collector terminals 140C and the base terminals 140B are exposed by the openings 145P of the common platform structure 145. For example, a width (or a diameter) W1 of the respective opening 145P is greater than a width (or a diameter) W2 of the corresponding contact plug 140. The subsequently-formed dielectric layer may be formed in the openings 145P and the subsequently-formed metallization pattern may be formed within the openings 145P to be in contact with the collector terminals 140C and the base terminals 140B as will be described later in accompanying with FIGS. 4A-4C.

With continued reference to FIGS. 3A-3B, the first portion CP1 of the common platform structure 145 may transversely and longitudinally extend beyond the active region R1. In some embodiments, the first portion CP1 of the common platform structure 145 spans over most or all of the active devices 120 in the active region R1 and even extends over most or all of the substrate 110. The first portion CP1 of the common platform structure 145 may be a single continuous layer made of metallic material(s), and this single continuous layer may not be used for signal routing in the resulting electronic device. In some embodiments, a ratio of an orthographic projection of the boundary 145B of the common platform structure 145 on the substrate 110 to an area of the first side 110a of the substrate 110 is over 80% to 90%, or even over 90%. In some embodiments, an orthographic projection of the distribution area 120D of the active devices 120 on the substrate 110 overlaps an orthographic projection of the common platform structure 145. For example, the boundary 145B of the common platform structure 145 is transversely and longitudinally between the edge 110e of the substrate 110 and the boundary RB1 of the active region R1. In some embodiments, the boundary 145B of the common platform structure 145 at least partially overlaps the boundary RB1 of the active region R1. It should be noted that the illustration of the plane view in FIG. 3B only shows the relative position of the substrate 110, the active devices 120, and the common platform structure 145, and other elements are omitted for the sake of clarity.

With continued reference to FIGS. 3C and 3A, the active devices 120 are shown as a device layer DL1 where the active devices 120 are implemented as HBTs, the base terminals 140B and the collector terminals 140C may be respectively arranged in separate zones, while the emitter terminals 140E may be arranged in several separate zones beside the base terminals 140B and the collector terminals 140C and spaced apart from the base terminals 140B and the collector terminals 140C. The exemplary configurations or shapes of the base terminals 140B, the collector terminals 140C and the emitter terminals 140E are merely schematic and do not reflect the physical outlines, conformation or layout patterns of these elements, and the numbers or sizes of these elements shown in the drawing are not intended to limit the scope of this disclosure. In some embodiments, the emitter terminals 140E of substantially all (or a majority, e.g., more than about 80%) the devices in the device layer DL1 are connected to the first portion CP1 of the common platform structure 145, regardless the locations of the emitter terminals 140E, thereby consolidating substantially all (or a majority, e.g., more than about 80%) emitter terminals 140E onto the same first portion CP1 of the common platform structure 145. In some embodiments, the first portion CP1 of the common platform structure 145 functions as a macro ground plane (common ground plane) in the resulting structure for all the devices in the device layer DL1. The first portion CP1 of the common platform structure 145 serves as a macro ground plane and minimizes the parasitic ground inductance incurring on the emitter terminals, leading to better electrical performance, especially for high frequency devices.

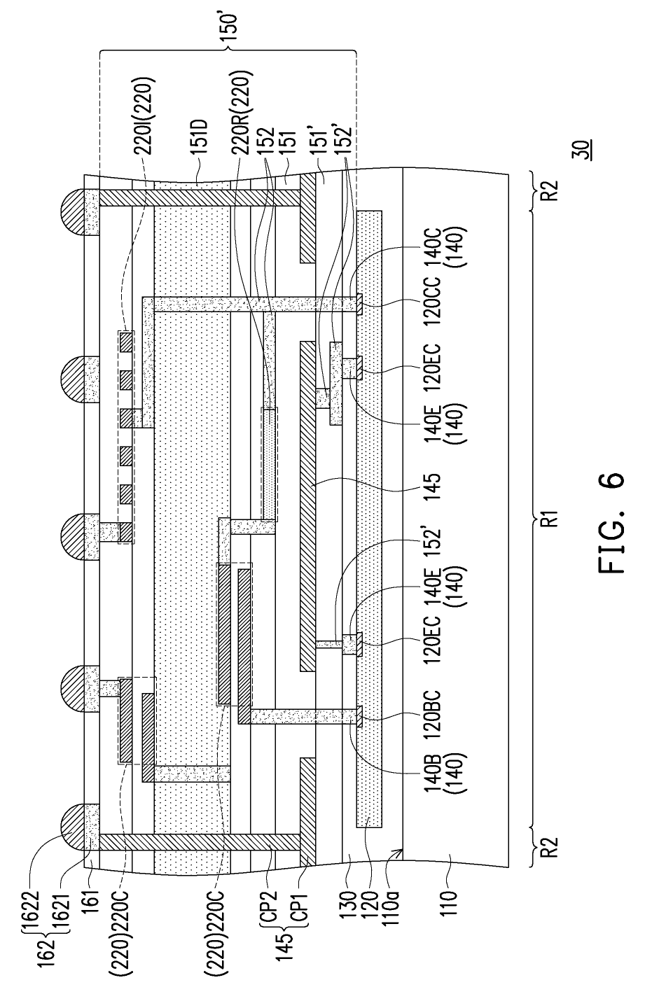

Still referring to FIG. 3C and FIG. 3A, in some embodiments, the electrical connection between each emitter terminal 140E and the first portion CP1 of the common platform structure 145 is optionally established through at least one vertically extending conductive plugs or metallic via plugs EV1 for establishing shorter or shortest paths of electrical connection (see the left one of additional metallization patterns 152’ shown in FIG. 6). Note that the elements corresponding to the metallic via plugs EV1 are not shown in the cross-sectional view of FIG. 3A, but are shown in FIG. 6. The dashed boxes on the first portion CP1 of the as shown in FIG. 3C may be considered as contact locations of the subsequently-formed second portion, and the first portion CP1 of the common platform structure 145 functions as the platform connecting and in contact with the emitter terminals 140E. Furthermore, because substantially all (or a majority, e.g., more than about 80%) the emitters of the device layer/level are connected to the common platform structure 145 which will be connected through metal connections to the ground pads/plane of the resulting structure, shorter or shortest paths of metal connection between the emitters to the ground is established, minimizing the unwanted extra inductance and further improving MMIC performance. In some embodiments, the first portion CP1 of the common platform structure 145 is formed with openings G1 and G2, and the locations of the openings G1, G2 may correspond to (or vertically aligned with) the locations of the base terminal 140B and the collector terminal 140C, so that the connections between the base terminals 140B and its corresponding contacts and the connections between the collector terminals 140C and its corresponding contacts pass through the openings G1 and G2 of the common platform structure 145.

Referring to FIG. 4A and FIG. 3A, an interconnect structure 150 is formed over the first side 110a of the substrate 110 to cover the dielectric layer 130 and the first portion CP1 of the common platform structure 145. The interconnect structure 150 may include at least one dielectric layer 151 and metallization patterns 152 embedded in the dielectric layer 151. It is understood that the dielectric layer 151 may include multiple dielectric sub-layers and the metallization patterns 152 may be sandwiched between adjacent dielectric sub-layers. For example, the dielectric sub-layers are formed by spin-coating, plasma-enhanced chemical vapor deposition (PECVD), or other suitable process. To maintain reasonable surface topology after multiple dielectric sub-layers and metallization patterns 152 have been stacked up, a surface planarization process may be performed for the success of the following lithography processes. In some embodiments, the metallization patterns 152 include conductive pads and conductive lines that may extend horizontally over the top surface 130t of the dielectric layer 130. The metallization patterns 152 may include conductive vias vertically extending to electrically couple adjacent active devices 120 through the contact plugs 140. In some embodiments, the metallization patterns 152 re-route the electrical signals of the active devices 120 and considered as routing wiring patterns.

With continued reference to FIGS. 4A and 3A, one or more passive device(s) 220 is formed in the dielectric layer 151 of the interconnect structure 150 and electrically coupled to the metallization patterns 152 of the interconnect structure 150. For example, the dielectric sub-layers and metal layers are built up layer-by-layer and sequentially to form the passive devices 220 and form electrical and thermal connection among devices. The electrical connections between the passive devices 220 and active devices 120 may be realized by the metallization patterns 152. The passive devices 220 are formed within the active region R1. In some embodiments, a substantial portion of the passive devices 220 are stacked over the active devices 120. The first portion CP1 of the common platform structure 145 may vertically separate the active devices 120 from the passive devices 220. In some embodiments, substantially all the active devices 120 needed for the MMIC are disposed below the first portion CP1 of the common platform structure 145, and substantially all (or a majority, e.g., more than about 80%) of the passive devices needed for the MMIC are disposed over the first portion CP1 of the common platform structure 145.

The passive devices 220 may be or include inductors 220I (e.g., planar spiral inductors, solenoidal inductors, or the like), capacitors 220C (e.g., metal-insulator-metal (MIM) capacitors or the like), resistors 220R, the like, a combination thereof, etc. The passive devices 220 may be used in various combinations for the application of interconnecting, filtering, impedance matching, termination, decoupling, the like, a combination thereof, etc. It should be noted that the arrangement of the passive devices 220 shown in FIG. 4A is merely an example, and the passive devices 220 may have a different arrangement than shown.

With continued reference to FIGS. 4A and 3A, after forming the interconnect structure 150, conductive features 162 and/or a protective layer 161 may be formed on the interconnect structure 150 to form an electronic device 10. In some embodiments, the electronic device 10 is referred to as a three-dimensional (3D) MMIC power amplifier die. In some embodiments, the conductive features 162 embedded in the protective layer 161 are electrically coupled to the active devices 120 through the contact plugs 140 and the interconnect structure 150. The conductive features 162 may be electrically coupled to the passive devices 220 through the metallization patterns 152 of the interconnect structure 150. The material of the protective layer 161 may be different from or the same as that of the dielectric layer 130. The conductive features 162 may include one or more conductive material(s) such as metals, alloys or other suitable metallic materials. The respective conductive feature 162 may be or include a contact pad, a contact via, a bump, or a combination thereof. In some embodiments, the respective conductive feature 162 includes a conductive pad 1621 and a conductive bump 1622 formed on the conductive pad 1621, and the protective layer 161 at least laterally covers the conductive pad 1621. The respective conductive bump 1622 may include one or more conductive material(s). In some embodiments, the respective conductive bump 1622 includes a solder material and a reflow process is performed on the solder material to form a desired bump shape. In some other embodiments, the respective conductive bump 1622 includes a pillar portion and a cap portion overlying the pillar portion, where the pillar portion and the cap portion are made of different materials (e.g., copper and solder, or other suitable conductive materials). The conductive bumps 1622 may be omitted according to alternative embodiments. The metallization patterns 152 of the interconnect structure 150 electrically couples the overlying conductive features 162 with some of the underlying contact plugs 140.

In alternative embodiments, the conductive features 162 are bonding features and a planarization process (e.g., CMP, grinding, etc.) is optionally performed on the bonding structure 160 for forming a smoother and levelled surface for assisting bonding. For example, through the fine planarization process, the top surfaces of the conductive features 162 and the protective layer 161 may be substantially coplanar to facilitate the subsequently-performed bonding process (if desired).

Still referring to FIG. 4A, a second portion CP2 of the common platform structure 145 is formed in the interconnect structure 150 and lands on the first portion CP1. For example, the second portion CP2 physically connects the first portion CP1 to the corresponding conductive features 162. The second portion CP2 of the common platform structure 145 may be embedded in the dielectric layer 151 of the interconnect structure 150 and laterally encircle the passive devices 220. In some embodiments, the passive devices 220 are completely or partially encircled by the second portion CP2 of the common platform structure 145. In other words, the passive devices 220 are laterally surrounded by the region defined by the second portion CP2. In some embodiments, the second portion CP2 and the first portion CP1 of the common platform structure 145 are physically isolated from the passive devices 220 by the dielectric layer 151. The second portion CP2 of the common platform structure 145 may be or include conductive vias penetrating through the sub-layers of the dielectric layer 151 and providing vertical and electrical path between the first portion CP1 and the overlying conductive features 162. It should be noted that although the second portion CP2 of the common platform structure 145 illustrated as a straight path between the first portion CP1 and the corresponding conductive features 162, the second portion CP2 may include traces/lines to re-route the path between the first portion CP1 and the overlying conductive features 162, in accordance with some embodiments. The second portion CP2 may be made of suitable conductive material (e.g., copper, copper alloys, etc.) and/or include one or more highly thermally conductive materials and functions as a heat transfer element.

In some embodiments, the second portion CP2 of the common platform structure 145 is referred to as metal connection paths. The locations of the metal connection paths are arranged in the peripheral region R2 of the electronic device 10 and/or adjacent to or at the corners of the first portion CP1. In some embodiments, the second portion CP2 of the common platform structure 145 may be formed in the peripheral region R2. In some other embodiments, the second portion CP2 of the common platform structure 145 is disposed at a boundary of the active region R1 or the peripheral region R2. This arrangement gives maximal undisturbed area in the center region of the electronic device 10 and can provide higher flexibility for the design and layout of the passive devices 220 that are disposed above the active devices 120. It is preferred and beneficial to form a connection path with shortest length and to have more than one metal connection paths in the common platform structure 145. It is appreciated that the presence of grounding inductance at the common emitter terminal degrades the amplifier’s performance. While the metal connection paths of the common platform structure 145 inherently exhibit inductive characteristics, increasing the number of these paths and minimizing the length of the paths may effectively reduce the overall grounding inductance, due to the parallel connection (or shunt connection) of the multiple shorter or shortest metal connection paths.

Referring to FIG. 4B and FIG. 4A, the passive devices 220 are formed within the area encircled by the second portion CP2 of the common platform structure 145. For example, an orthographic projection of the distribution area 220D of the passive devices 220 on the substrate 110 overlaps an orthographic projection of the distribution area 120D of the active devices 120 on the substrate 110. In some embodiments, the distribution area 220D of the passive devices 220 is beyond the distribution area 120D of the active devices 120 in a top plan view. The orthographic projection of the distribution area 220D of the passive devices 220 on the substrate 110 may be within the orthographic projection of the distribution area 120D of the active devices 120 on the substrate 110 or the orthographic projections of the distribution areas 220D and 120D may substantially coincide with each other. In some embodiments, the orthographic projection of the distribution area 220D of the passive devices 220 on the substrate 110 is greater than that of the distribution area 120D of the active devices 120. The distribution area 120D of the active devices 120 may be within the active region R1 or substantially coincide with the active region R1. The distribution area 220D of the passive devices 220 may be within the active region R1 or substantially coincide with the active region R1. The protective layer 161 may fully cover the distribution areas (120D and 220D) and the boundary 145B of the common platform structure 145, in the plane view. Similar to FIG. 3B, the illustration of FIG. 4B only shows the relative position of the substrate 110, the active devices 120, the passive devices 220, the common platform structure 145, and the protective layer 161, and some elements are omitted for the sake of clarity. In addition, it should be noted that the exemplary shapes of the elements shown in FIG. 4B are merely schematic and do not reflect the physical outlines, conformation or layout patterns of these elements, and the sizes of these elements shown in the drawing are not intended to limit the scope of this disclosure.

Referring to FIG. 4C and with reference to FIGS. 4A-4B and 3B-3C, the base terminals 140B and the collector terminals 140C are not physically connected with the common platform structure 145. For example, the base terminals 140B are connected with contacts BC1 formed within the opening G1, and the collector terminals 140C are connected with contacts CC1 formed within the openings G2. Such layout design allows the base terminals 140B and collector terminals 140C to pass through the first portion CP1 of the common platform structure 145. The contacts BC1 and the base terminal 140B are electrically connected, the contacts CC1 and the collector terminal 140C are electrically connected, and such electrical connections are not limited to the exemplary plugs as illustrated in the figures. It is understood that the electrical connection may be established through one or more vertically extending conductive vias or metallic through vias for establishing shorter paths of electrical connection, and metallization patterns 152 including traces/lines in the interconnect structure 150 may be incorporated.

In some embodiments, the common platform structure 145 is thermally connected with the contact plug 140 (e.g. common emitter terminals 140E) of the active device(s) 120 for assisting heat transferring and thermal dissipation, and functions as a heat transfer bar or a part of thermal-dissipation path in the electronic device 10. The disposition of the common platform structure 145 excels in controlling thermal runaway issues, significantly improving the device's thermal management capabilities through optimized heat dissipation structures, thereby enhancing overall MMIC reliability.

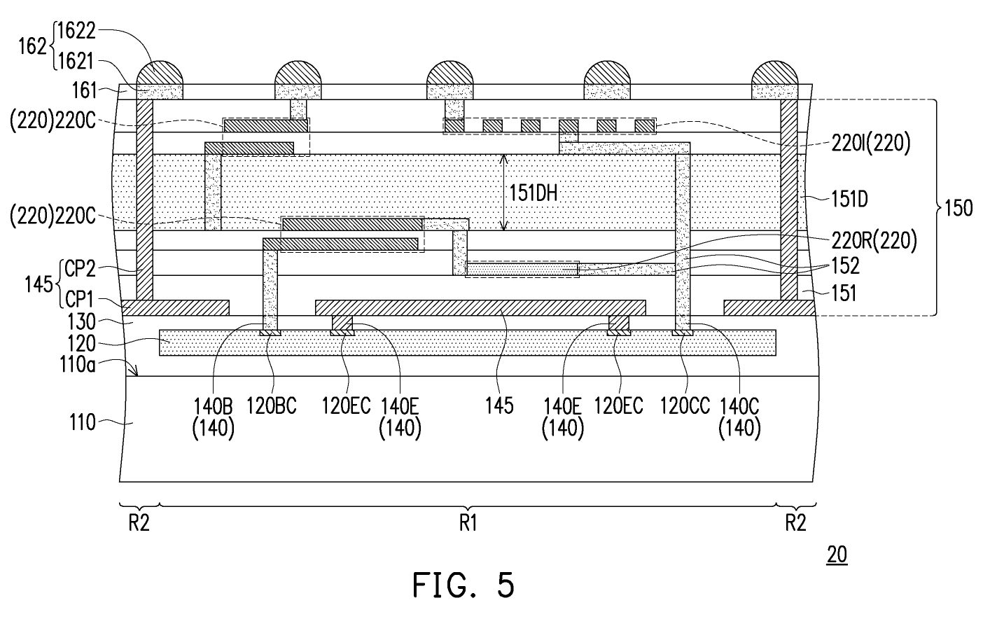

FIGS. 5-6 are schematic cross-sectional views of an electronic device including a common platform structure, in accordance with various embodiments. Referring to FIG. 5 and FIG. 4A, the electronic device 20 is similar to the electronic device 10, except that at least one of the sub-layers of the dielectric layer 151 of the interconnect structure 150 is replaced with a thicker dielectric sub-layer 151D. In some embodiments, the dielectric sub-layer 151D having the thickness 151DH is the thickest among sub-layers of the dielectric layer 151. For example, the dielectric sub-layer 151D vertically separates the inductors 220I fully or partially overlying the dielectric sub-layer 151D from the capacitors 220C fully or partially underlying the dielectric sub-layer 151D. The capacitors 220C made of conductive material(s) may be considered as conductive features according to some embodiments. In some embodiments where no passive device is disposed below the dielectric sub-layer 151D, the dielectric sub-layer 151D vertically separates the overlying passive device 220 from conductive features (e.g., the first portion CP1, other metallization patterns 152, or the like) fully or partially underlying the dielectric sub-layer 151D.

In some embodiments, a ratio of the thickness 151DH of the dielectric sub-layer 151D to the total thickness of the dielectric material underlying the first portion CP1 of the common platform structure 145 including the dielectric layer 130 is in a range of about 1 and about 20. If the ratio is greater than 20, the conductive vias of the metallization patterns 152 penetrating through the dielectric sub-layer 151D to connect the overlying passive device 220 (e.g., the inductors 220I disposed over the dielectric sub-layer 151D) and the underlying active device 120 may be too long to cause unwanted signal loss. In addition, If the ratio is greater than 20, the conductive vias of the metallization patterns 152 penetrating through the dielectric sub-layer 151D becomes a via with high aspect ratio. However, the high aspect ratio of the via may pose difficulties for etching and/or metal-filling (e.g., plating or evaporation) processes. For example, unwanted voids/seams may be formed in the via with high aspect ratio. Moreover, if the dielectric sub-layer 151D is too thick, the peeling or cracking may occur at the interface associated with the dielectric sub-layer 151D due to internal stress. If the ratio is less than 1, the overlying passive device 220 (e.g., the inductors 220I disposed over the dielectric sub-layer 151D) may be too close to the first portion CP1 of the common platform structure 145, and eddy current may be generated and may negatively affect the electrical property of the inductors. The uniformity control of the thickness of the dielectric sub-layer may be difficult when the ratio is less than 1. For example, leakage or short circuits may easily occur at the regions of the dielectric sub-layer which are too thin, and/or the ability to balance the unevenness of the underlying metallic features may reduce. By configuring the dielectric sub-layer 151D in the interconnect structure 150, the unwanted coupling and interference between the passive device 220I (e.g., spiral inductor) and the passive device (capacitors 220C, e.g., MIM capacitor) are reduced. The configuration of the dielectric sub-layer 151D may be designed for alleviating the coupling effect and interference between the stacked passive devices 220 formed in the interconnect structure 150. The dielectric sub-layer 151D may be formed by multiple spin coating cycles, PECVD process, or the like. In alternative embodiments, the dielectric sub-layer 151D is pre-fabricated dielectric sheet and adhered onto the underlying dielectric sub-layer using an adhesive. This allows for precise control of the thickness 151DH of the dielectric sub-layer 151D and may be advantageous in processes where additional thermal or deposition steps need to be minimized.

Referring to FIG. 6 and FIG. 5, the electronic device 30 is similar to the electronic device 20, except that the interconnect structure 150’ of the electronic device 30 includes a lower portion and an upper portion and the first portion CP1 of the common platform structure 145 is interposed between the lower and upper portions. For example, the lower portion of the interconnect structure 150’ includes an additional dielectric layer 151’ overlying the dielectric layer 130 and an additional metallization patterns 152’ embedded in the additional dielectric layer 151’. The additional metallization patterns 152’ may include a conductive via, a conductive pad, a conductive line, a combination thereof, etc. For example, the additional metallization patterns 152’ connects the contact plugs 140 (e.g., the common emitter terminals 140E) to the first portion CP1 of the common platform structure 145. Note that a portion of the additional metallization patterns 152’ laterally covered by the additional dielectric layer 151’ may be viewed as the metallic via plugs (e.g., EV1 labeled in FIG. 3C). In some embodiments, additional passive device (not shown) may be formed in the lower portion of the interconnect structure 150’ underlying the first portion CP1 of the common platform structure 145. In some embodiments, the interconnect structure 150’ and the common platform structure 145 formed by: depositing the additional dielectric layer 151’ on the dielectric layer 130; forming the additional metallization patterns 152’ in the additional dielectric layer 151’ to form the lower portion; forming the first portion CP1 of the common platform structure 145 on the lower portion; forming the dielectric layer 151 and the metallization patterns 152 to form the upper portion on the first portion CP1 of the common platform structure 145; and forming the second portion CP2 of the first portion CP1 of the common platform structure 145 during the formation of the upper portion. The first portion CP1 of the common platform structure 145 may thus be interposed between the upper portion and the lower portion of the interconnect structure 150’.

Based on the above, the electronic device 10 (or 20, 30) includes a substantial portion of the passive devices 220 of the power amplifier circuit stacked over the distribution area of the active devices 120. The passive devices 220 are fabricated by building up dielectric sub-layers and metallization patterns. With the stack-up arrangement of the passive devices 220, the footprint of the electronic device 10 (or 20, 30) may be significantly shrunk, as compared to the footprint of the conventional MMIC. In addition, the electronic device 10 (or 20, 30) includes the common platform structure 145 having the first portion CP1 and the second portion CP2 thermally and electrically connected to the first portion CP1, the first portion CP1 is vertically between the distribution areas of the active devices 120 and the passive devices 220, and the second portion CP2 laterally encircles the distribution area of the passive devices 220. The second portion CP2 (e.g. metal connection paths) extends from the first portion CP1 to the conductive features 162 (e.g. conductive pads 1621) on the top surface of the electronic device 10 (or 20, 30). The common emitter terminals 140E of the active devices 120 are electrically and thermally coupled to the first portion CP1 of the common platform structure 145. Heat generated from the active devices 120 is dispersed more uniformly across the first portion CP1 of the common platform structure 145. The dispersed heat is subsequently transferred to the conductive features 162 and then to the exterior of the electronic device 10 (or 20, 30). Heat dissipation of the electronic device 10 (or 20, 30) may be greatly improved over the conventional MMIC. The undesired grounding inductance at the common emitter terminals 140E can be effectively reduced. The second portion CP2 (e.g. metal connection paths) are arranged at the peripheral region of the first portion CP1 and also peripheral region of the electronic device 10 (or 20, 30). With this arrangement, there can be a maximized open area that is minimally penetrated by the metal connection paths. Since a substantial portion of the passive devices 220 is stacked right above the active devices 120 and the open area is therefore very beneficial for the design and layout of the passive devices 220 of the electronic device 10 (or 20, 30).

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. An electronic device, comprising:
a substrate;
an active device disposed over the substrate;
an interconnect structure disposed over and electrically coupled to the active device;
a passive device disposed over the active device and embedded in the interconnect structure, the passive device being electrically coupled to the active device through the interconnect structure; and
a common platform structure comprising a first portion and a second portion connected to the first portion, the first portion being vertically between the active device and the passive device, a portion of the active device being electrically and thermally coupled to the first portion, and the passive device being laterally encircled by the second portion.

2. The electronic device of claim 1, wherein the active device is a heterojunction bipolar transistor and a common emitter terminal of the heterojunction bipolar transistor is connected to the first portion of the common platform structure.

3. The electronic device of claim 1, wherein the first portion of the common platform structure comprises openings and a metallization pattern passes through the openings to connect the active device.

4. The electronic device of claim 1, wherein an orthographic projection of an area of the active device on the substrate overlaps an orthographic projection of the first portion of the common platform structure on the substrate and an orthographic projection of an area of the passive device on the substrate.

5. The electronic device of claim 4, wherein the orthographic projection of the first portion of the common platform structure is greater than the orthographic projection of an area of the active device.

6. The electronic device of claim 1, wherein the second portion of the common platform structure is arranged in a peripheral region of the electronic device.

7. The electronic device of claim 1, further comprising:
a dielectric layer overlying the active device, the dielectric layer comprising a planarized top surface over which the first portion of the common platform structure is disposed.

8. The electronic device of claim 1, wherein the electronic device is a monolithic microwave integrated circuit (MMIC) die.

9. The electronic device of claim 1, wherein the common platform structure is electrically grounded.

10. The electronic device of claim 1, wherein the interconnect structure comprises dielectric sub-layers and metallization patterns embedded in the dielectric sub-layers, the dielectric sub-layers comprise a thickest sub-layer vertically separating a first device of the passive device overlying the thickest sub-layer from conductive features underlying the thickest sub-layer.

11. A manufacturing method of an electronic device, comprising:
forming an active device over a substrate;
forming a first portion of a common platform structure over the active device, wherein a portion of the active device is connected to the first portion of the common platform structure;
forming an interconnect structure over the first portion of the common platform structure;
forming a passive device over the first portion of the common platform structure and in the interconnect structure, wherein the active device is electrically coupled to the passive device through the interconnect structure; and
forming a second portion of the common platform structure on the first portion and in the interconnect structure, wherein the passive device is laterally encircled by the second portion.

12. The manufacturing method of claim 11, further comprising:
forming a dielectric layer on the substrate to cover the active device;
leveling a top surface of the dielectric layer; and
forming the first portion of the common platform structure over the top surface of the dielectric layer.

13. The manufacturing method of claim 12, further comprising:
forming contact plugs in the dielectric layer to connect the active device;
performing the smoothing process on the dielectric layer and the contact plugs; and
forming the first portion of the common platform structure on the dielectric layer and the contact plugs, wherein the first portion of the common platform structure is electrically and thermally coupled to the active device through the contact plugs.

14. The manufacturing method of claim 11, wherein forming the active device over the substrate comprises:
forming a heterojunction bipolar transistor over the substrate, wherein after forming the first portion of the common platform structure, a common emitter terminal of the heterojunction bipolar transistor is connected to the first portion of the common platform structure.

15. The manufacturing method of claim 11, wherein forming the first portion of the common platform structure comprises:
forming a metallic sheet over the active device, wherein an orthographic projection of an area of the active device on the substrate overlaps an orthographic projection of the metallic sheet on the substrate, and the orthographic projection of the metallic sheet is greater than the orthographic projection of the area of the active device.

16. The manufacturing method of claim 15, wherein the metallic sheet is provided with openings and forming the interconnect structure comprises:
forming a metallization pattern passing through the openings to connect the active device.

17. The manufacturing method of claim 11, wherein forming the second portion of the common platform structure comprises:
forming conductive vias passing through a dielectric layer of the interconnect structure to land on the first portion of the common platform structure, wherein the conductive vias are formed in a peripheral region of the first portion of the common platform structure.

18. The manufacturing method of claim 11, wherein forming the interconnect structure and the first portion of the common platform structure comprises:
forming a lower portion of the interconnect structure on the active device;
forming the first portion of the common platform structure on the lower portion of the interconnect structure; and
forming an upper portion of the interconnect structure on the first portion of the common platform structure.

19. The manufacturing method of claim 11, wherein forming the interconnect structure and forming the passive device comprise:
alternately forming dielectric sub-layers and metallization patterns; and
forming the passive device on at least one of the dielectric sub-layers to connect at least one of the metallization patterns.

20. The manufacturing method of claim 19, wherein forming the dielectric sub-layers comprises:
forming a lower sub-layer over a first device of the passive device;
forming an upper sub-layer on a lower sub-layer, wherein the upper sub-layer is thicker than the lower sub-layer; and
forming a second device of the passive device over the upper sub-layer.
